(19) United States
(12) Patent Application Publication
(10) Pub. No.: US 2024/0413291 A1
(43) Pub. Date: Dec. 12, 2024

(54) Light Emitting Diode and Fabrication Method Thereof

(71) Applicant: XIAMEN SANAN OPTOELECTRONICS TECHNOLOGY CO., LTD., Xiamen (CN)

(72) Inventors: Su-Hui Lin, Xiamen (CN); Lingyuan Hong, Xiamen (CN); SHENG-HSIEN HSU, Xiamen (CN); Sihe CHEN, Xiamen (CN); Dazhong CHEN, Xiamen (CN); Gong CHEN, Xiamen (CN); CHIA-HUNG CHANG, Xiamen (CN); KANG-WEI PENG, Xiamen (CN)

(73) Assignee: XIAMEN SANAN OPTOELECTRONICS TECHNOLOGY CO., LTD., Xiamen (CN)

(21) Appl. No.: 18/811,718

(22) Filed: Aug. 21, 2024

Related U.S. Application Data
(63) Continuation of application No. 16/147,604, filed on Sep. 29, 2018, now abandoned.

(30) Foreign Application Priority Data
Oct. 16, 2017 (CN) 201710963559.8

(51) Int. Cl. H01L 33/62; H01L 27/15; H01L 33/00; H01L 33/10; H01L 33/14; H01L 33/38; H01L 33/42

(52) U.S. Cl. CPC H01L 33/62; H01L 27/153; H01L 33/0075; H01L 33/10; H01L 33/14; H01L 33/38; H01L 33/42

(57) ABSTRACT

A light-emitting diode includes a first semiconductor layer, a light-emitting layer and a second semiconductor layer, having an upper surface providing a first electrode area containing a pad area and an extended area; a transparent conductive layer over the first semiconductor layer having a first opening to expose a portion of a surface of the first semiconductor layer corresponding to the pad area; a protective layer over the transparent conductive layer having a second opening and a third opening respectively at positions corresponding to the pad area and the extended area, while exposing a portion of the surface of the first semiconductor layer corresponding to the pad area and a portion of a surface of the transparent conductive layer corresponding to the extended area; and a first electrode over the protective layer directly contacting the first semiconductor layer corresponding to the pad area via the first and second openings.

### CROSS-REFERENCE TO RELATED APPLICATIONS

This is a continuation of U.S. patent application Ser. No. 16/147,604 filed on Sep. 29, 2018, which claims priority to Chinese Patent Application No. 201710963559.8 filed on Oct. 16, 2017. The disclosures of the above-referenced applications are hereby incorporated by reference in their entirety.

### BACKGROUND

Due to long service life, high vibration resistance, low heat emission and low power consumption, light-emitting diodes have been widely applied in domestic appliances, as well as in instruments as indicators or light sources.

Early GaN-based LED chip production processes commonly comprise four procedures, i.e., MESA etching, transparent conductive layer (such as ITO) production, electrode production and protective layer production. A light-emitting diode produced by following such a process is shown in FIG. 1, generally comprised a substrate 101, a N-type layer 111, a light-emitting layer 112, a P-type layer 113, a transparent conductive layer 120, a P electrode 141 (pad 143 and extension branch 144), a N electrode 142 and a protective layer 130. In GaN-based LED, the p-GaN layer commonly causes a current congestion at the pad bottom due to its low carrier mobility. Therefore, a current blocking layer 150 is commonly added at the bottom of the P-type electrode to inhibit excessive current injection and enhance current dispersion of the transparent conductive layer, as shown in FIG. 2. The chip production process commonly and at least includes five procedures, i.e. MESA etching, current blocking layer production, current dispersion layer (e.g., ITO) production, electrode production and protective layer production.

### SUMMARY

The present invention provides a light-emitting diode and its fabrication method, wherein forming a transparent conductive layer, then forming a productive layer, and making the electrodes last, so that the protective layer can simultaneously serve as a current blocking layer, thereby reducing the procedures on one hand and effectively enhancing the luminous efficiency of the light-emitting diode on the other hand.

A light-emitting diode as one aspect of the present invention comprises: an epitaxial laminate, including a first semiconductor layer, a light-emitting layer and a second semiconductor layer from up to down, and having a upper surface which providing an electrode area containing a pad area and an extended area; a transparent conductive layer, forming on the first semiconductor layer, having a first opening to exposing a part surface of the first semiconductor layer corresponding to the pad area; a protective layer, forming on the transparent conductive layer, having a second opening and a third opening respectively at a position corresponding to the pad area and the extended area, while exposing a part surface of the first semiconductor layer corresponding to the pad area and a part surface of the transparent conductive layer corresponding to the extended area; a first electrode, forming on the protective layer, and directly contacting the first semiconductor layer corresponding to the pad area via the first and second openings.

The present invention simultaneously provides a light-emitting diode production method, including the following steps: (1) Forming a epitaxial laminate, including a first semiconductor layer, a light-emitting layer and a second semiconductor layer from up to down in sequence, and having a upper surface; (2) Defining a first electrode area on the upper surface of the epitaxial laminate, the first electrode area including a pad area and an extended area; (3) Depositing a transparent conductive layer on the epitaxial laminate, and forming a first opening in the pad area to exposing a part surface of the first semiconductor surface; (4) Depositing a protective layer on the transparent conductive layer, and forming a second opening and a third opening respectively in the pad area and extended area of the first electrode area, while exposing a part surface of the semiconductor layer in the pad area and a part surface of the transparent conductive layer in the extended area; (5) Forming a first electrode on the protective layer which directly contacting the first semiconductor layer in the pad area via the first and second openings.

In some embodiments, the upper surface of epitaxial laminate further providing a second electrode area; and a mesa is formed on the second electrode area to expose a part of the surface of the second semiconductor layer; the protective layer covers the surface of the mesa and has a fourth opening. Further, the light-emitting diode further comprising a second electrode which is formed on the protective layer, and including a pad and an extension branch; a portion of the upper surface of the extension branch is higher than an upper surface of the first electrode corresponding to the pad area.

In other embodiments, t the second opening has a larger size than the first opening, and the first electrode is in contact with the first semiconductor layer and the transparent conductive layer simultaneously in the pad area.

In other embodiments, the second opening is an annular structure which having an inner-ring diameter be smaller than the diameter of the first opening, and an outer-ring diameter be larger than the diameter of the first opening.

Preferably, the protective layer has a thickness d of λ/4n×(2k−1), where λ is the emission wavelength of the light emitting layer, n is the refractive index of the protective layer, and K is a natural number greater than 1. Preferably, k is a natural number greater than 2. In some implementations, the protective layer can be 200-250 nm thick.

In other embodiments, the first electrode has an upper surface that is undulated in the extended area.

In other embodiments, the first electrode having an upper surface which a portion in the extended area is higher than the part of the upper surface in the pad area.

In other embodiments, the first electrode has a stepped pad.

In other embodiments, the protective layer has several fifth openings around the pad area to exposing a part of the transparent conductive layer; the first electrode leads several metal antennas to the fifth openings in the pad area to be contacted the transparent conductive layer.

In other embodiments, the second opening is annular and having at least one antenna extending away from the pad area; the first electrode be in contact with the transparent conductive layer through the said antenna.

A light-emitting diode according to the second aspect of the present invention comprises: an epitaxial laminate, including a first semiconductor layer, a light-emitting layer and a second semiconductor layer from up to down, and having a upper surface which providing an electrode area containing a pad area and an extended area; a transparent conductive layer, forming on the first semiconductor layer; a protective layer, forming on the transparent conductive layer, having a first opening and a second opening respectively in the pad area and extended area to exposing a part surface of the transparent conductive layer; wherein, the first opening is annular and having at least one antenna extending away from the pad area; a first electrode, forming on the protective layer, having direct electrical connection to the second semiconductor layer via the first and second openings.

In some embodiments, the upper surface of epitaxial laminate further providing a second electrode area; and a mesa is formed on the second electrode area to expose a part of the surface of the second semiconductor layer; the protective layer covers the surface of the mesa and has a third opening. Further, the light-emitting diode includes a second electrode on the protective layer; the second electrode is contact with the surface of the second semiconductor layer via the third opening structure.

In other embodiments, the antenna is located within the pad area.

In other embodiments, the antenna goes beyond the pad area.

Preferably, the number of antennae is 1-20.

In other embodiments, the transparent conductive layer having a fourth opening in the pad area to exposes a part surface of the first semiconductor layer in the pad area.

Preferably, the first opening has an inner-ring diameter be smaller than the diameter of the fourth opening, and an outer-ring diameter be larger than the diameter of the fourth opening.

In other embodiments, the first opening has an outer ring diameter be smaller than the diameter of the fourth opening; the antenna has an outer diameter be greater than the diameter of the fourth opening; and the diameter of the fourth opening is smaller than the diameter of the pad area.

A light-emitting diode according to the third aspect of the present invention comprising: including a first semiconductor layer, a light-emitting layer and a second semiconductor layer from up to down, and having a upper surface which providing an electrode area containing a pad area and an extended area; a transparent conductive layer forming on the first semiconductor layer; a protective layer forming on the transparent conductive layer, and having a several of first openings around the pad area and a second opening in the extended area to exposing a part surface of the first semiconductor layer; a first electrode forming on the protective layer and including a pad, an extension and an antenna, the antenna having its two ends connect to the pad and the transparent conductive layer via the first opening, the extension branch connecting to the transparent conductive layer via the second opening.

In some embodiments, the protective layer has a third opening which is annular in the pad area.

In other embodiments, the transparent conductive layer has a fourth opening structure in the pad area.

Preferably, the third opening has an inner ring diameter smaller than the diameter of the fourth opening, and an outer ring diameter greater than the diameter of the fourth opening.

Preferably, the diameter of the fourth opening is greater than the outer diameter of the third opening and smaller than the inside tangential circle diameter of the first opening.

In other embodiments, the pad has simultaneous contact with the protective layer and the transparent conductive layer.

In other embodiments, the upper surface of epitaxial laminate further providing a second electrode area; and a mesa is formed on the second electrode area to expose a part of the surface of the second semiconductor layer; the protective layer covers the surface of the mesa and has a fifth opening. Further, the light-emitting diode further comprising a second electrode a second electrode formed on the protective layer; the second electrode is in contact with the second semiconductor surface via the fifth opening structure.

Preferably, the number of the antennae is 1-20.

A light-emitting diode according to the fourth aspect of the present invention comprising: an epitaxial laminate including a first semiconductor layer, a light-emitting layer and a second semiconductor layer from up to down; a transparent conductive layer formed on the first semiconductor layer; a protective layer formed on the transparent conductive layer; a first electrode included a pad and an extension branch, wherein the extension branch being formed on the protective layer and having electrical connection to the first semiconductor layer through a series of through holes, while partial upper surface of the extension branch being higher than the upper surface of the pad.

Preferably, the extension branch forms an omni-directional reflector with the protective layer.

Preferably, the protective layer is a layer of optically thinner medium.

In some embodiments, the transparent conductive layer has a first opening at the location corresponding to the pad.

In other embodiments, the protective layer has a second opening at the location corresponding to the pad.

Preferably, the second opening has a larger size than the first opening.

Preferably, the pad has simultaneous contact with the protective layer, the transparent conductive layer and the first semiconductor layer.

Preferably, the second opening is of annular structure, having its inner ring diameter smaller than and the outer ring diameter greater than the diameter of the first opening.

Preferably, the light-emitting diode further comprises a second electrode formed on the protective layer and includes a pad and an extension branch. Wherein, a partial upper surface of the extension branch of the second electrode being higher than the upper surface of the pad of the first electrode.

A light-emitting diode according to the fifth aspect of the present invention comprises: an epitaxial laminate including a first semiconductor layer, a light-emitting layer and a second semiconductor layer from up to down; a transparent conductive layer formed on the first semiconductor layer surface; a protective layer formed on the surface of the transparent conductive layer; a first electrode includes a first pad and a first extension branch, being electrically connected to the first semiconductor layer; a second electrode includes a second pad and an second extension branch, wherein the second extension branch being formed on the protective layer, being electrically connected to the second semiconductor via a several of through holes penetrating the protective layer, the transparent conductive layer, the first semiconductor layer and the light-emitting layer, and having a part upper surface higher than the upper surface of the first pad.

Preferably, the second extension branch form an omni-directional reflector with the protective layer.

Preferably, the protective layer is a layer of optically thinner medium.

In some embodiments, the transparent conductive layer has a first opening at a location corresponding to the pad of the first electrode.

In other embodiments, the protective layer has a second opening at the location corresponding to the first and second pads.

Preferably, the second opening has a larger size than the first opening.

In some embodiments, the first pad is stepped.

In other embodiments, the second extension branch is a closed-loop structure.

In other embodiments, the second pad has a partial upper surface higher than the upper surface of the first pad.

In other embodiments, the second electrode is distributed in the central area of the light-emitting diode, wherein the second pad being located at the center and the second extension branch extending from the pad to two opposite directions.

A light-emitting diode according to the sixth aspect of the present invention comprises: an epitaxial laminate including a first semiconductor layer, a light-emitting layer and a second semiconductor layer from up to down; a transparent conductive layer formed on the first semiconductor layer surface; a protective layer formed on the surface of the transparent conductive layer; a first electrode being electrically connected to the first semiconductor layer; a second electrode formed on the protective layer, includes a second pad and an second extension branch, and being electrically connected to the second semiconductor via a series of through holes, while the second pad having the upper surface at the same height with the upper surface of the second extension branch.

Preferably, the second extension branch form an omni-directional reflector with the protective layer.

Preferably, the ratio of the diameter of the though hole below the second pad to the diameter of the second pad is 1:2-1:20.

Preferably, the area of the through hole below the pad of the second electrode accounts for 2%-60% of the pad area of the second electrode.

In some embodiments, the first electrode includes a first pad and a first extension branch. Further, the transparent conductive layer has a first opening at the location corresponding to the first pad.

In other embodiments, the first electrode includes a first pad and a first extension branch. Further, the protective layer has a second opening at the location corresponding to the first pad.

In some embodiments, the first electrode includes a first pad and a first extension branch. Further, the transparent conductive layer has a first opening at the location corresponding to the first pad, the protective layer has a second opening at the location corresponding to the first pad. Preferably, the second opening has a larger size than the first opening. Preferably, the pad of the first electrode has simultaneous contact with the protective layer, the transparent conductive layer and the second semiconductor layer.

In some embodiments, the first electrode has a stepped pad.

In some embodiments, the second pad has partial upper surface higher than the pad upper surface of the first pad.

In some embodiments, the second electrode is distributed in the central area of the light-emitting diode, wherein the second pad being located at the center and the second extension branch extending from the second pad to two opposite directions.

A light-emitting diode according to the seventh aspect of the present invention comprises: an epitaxial laminate including a first semiconductor layer, a light-emitting layer and a second semiconductor layer from up to down; a transparent conductive layer formed on the first semiconductor layer surface; a protective layer formed on the surface of the transparent conductive layer; a first electrode being electrically connected to the first semiconductor layer; a second electrode formed on the protective layer and includes a second pad and a second extension branch, wherein the protective layer provided a first through hole below the second pad and a second through hole below the second extension branch, the first through holes having a diameter smaller than or equal to the diameter of the second through holes.

Preferably, the number of first through holes is above one; when there are more than one first through holes, the holes are distributed symmetrically about the center.

Preferably, the total area of first through holes accounts for 2%-50% of the second pad area.

Preferably, any single one of the first through holes accounts for 1%-5% of the second pad area.

In some embodiments, the upper surface of the second pad is flush with the upper surface of the second extension branch.

In some embodiments, the first electrode included a first pad and a first extension branch, and a series of third through holes are provided on the protective layer below the first extension branch, and a part surface of the transparent conductive layer is exposed.

In some embodiments, the first electrode included a first pad and a first extension branch, and the first is formed on the protective layer, and is in contact with the transparent conductive layer through the extension branch.

In some embodiments, the first electrode included a first pad and a first extension branch, and the transparent conductive layer has an opening structure below the first pad.

In some embodiments, the first electrode included a first pad and a first extension branch, and the protective layer has an opening structure below the first pad.

In some embodiments, the first electrode included a first pad and a first extension branch, and the first pad is a stepped pad.

A light-emitting diode according to the eighth aspect of the present invention comprises: an epitaxial laminate including a first semiconductor layer, a light-emitting layer and a second semiconductor layer from up to down; a transparent conductive layer formed on the first semiconductor layer surface; a protective layer formed on the surface of the transparent conductive layer; a first electrode included a first pad and a first extension branch, wherein the extension branch being formed on the protective layer, and being electrically connected to the transparent conductive layer via a series of first through holes penetrating the protective layer, and; a second electrode included a second pad and a second extension branch, wherein the extension branch being formed on the protective layer, and being connected to the second semiconductor layer via a series of second through holes penetrating the protective layer, the transparent conductive layer, the first semiconductor layer and the light-emitting layer, and; the first through holes have three or more holes arranged in order, whichin at least one among the three adjacent first through holes having a distance to its nearest second through hole is not exceeding the distance between the first extension branch and the second extension branch.

In some embodiments, the first extension branch is parallel to the second extension branch.

In some embodiments, at least one among three adjacent first through holes has a connecting line with its nearest second through hole is perpendicular to the first extension branch.

In some embodiments, y, the distance d1 between two adjacent first through holes and the distance d2 between two adjacent through holes meets the following condition: d2>2d1.

In some embodiments, the transparent conductive layer has a first opening structure under the first pad to expose a part surface of the second semiconductor layer. Further, the protective layer has a second opening structure below the first pad. Preferably, the second opening has a larger size than the first opening.

In some embodiments, the first pad is a stepped pad.

Preferably, the first extension branch has an undulated upper surface.

Preferably, the second extension branch has an undulated upper surface.

A light-emitting diode according to the ninth aspect of the present invention, comprises: an epitaxial laminate including a first semiconductor layer, a light-emitting layer and a second semiconductor layer from up to down; a transparent conductive layer formed on the first semiconductor layer surface; a protective layer formed on the surface of the transparent conductive layer; a first electrode, being electrically connected to the first semiconductor layer; a second electrode formed on the protective layer and included a second pad and a second extension branch, wherein the protective layer having a first opening structure provided below the second pad to expose a part surface of the second semiconductor layer, and the pad being simultaneously in contact with the second semiconductor layer and the protective layer.

In some embodiments, the first opening is of an annularity form.

In some embodiments, the first electrode includes a first pad and a first extension branch, wherein the transparent conductive layer having a second opening structure below the first pad to exposed part of the first semiconductor layer. Further, the protective layer having a third opening structure below the first pad. Preferably, the third opening has a larger size than the second opening.

In other embodiments, the first electrode has a stepped pad.

In other embodiments, the first electrode include a first pad and a first extension branch, and the first extension branch has an undulated upper surface.

In some embodiments, the first electrode includes a first pad and a first extension branch, and the first pad has its upper surface lower than partial upper surface of the first extension branch.

In some embodiments, the first electrode includes a first pad and a first extension branch, and the first pad has its upper surface lower than partial upper surface of the second extension branch.

In some embodiments, the second extension branch has an undulated upper surface.

The present invention at least has the following advantageous effects:

The said light-emitting diode first has a protective layer formed on the transparent Cconductive layer before electrodes are formed; the protective layer protects the light-emitting diode from damage on one hand, and can directly serve as a current blocking layer to inhibit excessive current injection and enhance current dispersion of the transparent conductive layer;

The said light-emitting diode has its first electrode in direct contact with the semiconductor layer in the pad area to effectively improve the adhesion between the electrode and the epitaxial layer and reduce the risk of the electrode being separated from the adhesion interface upon routing;

Antennae are formed around the pad area of the first electrode to increase the contact area between the pad area of the first electrode and the transparent conductive layer, relieve current congestion on the pad area and the extended area, and reduce the risk of the electrode metal being extracted and burnt;

(4) The protective layer is designed with refraction effect to effectively reduce the light blocking area of metal in the extended area of the electrode and improve the LED extraction efficiency;

The protective layer is designed to be an omni-directional reflector, capable of improving the reflectivity of the electrode extended area and reducing light absorption efficiency;

The said light-emitting diode first has a protective layer formed on the transparent conductive layer before electrode formation, thereby reducing possible oxidation of active metal in the electrode structure during formation of the protective layer.

The said light-emitting diode is produced by combing current blocking layer and protective layer procedures into one procedure, having simplified the process.

In another aspect, a light-emitting system is provided including a plurality of the light-emitting diodes described above. The light-emitting system can be a system of display, lighting, signage, etc.

The other features and advantages of this present disclosure will be described in detail in the following specification, and it is believed that such features and advantages will become more obvious in the specification or through implementations of this invention. The purposes and other advantages of the present disclosure can be realized and obtained in the structures specifically described in the specifications, claims and drawings.

While the invention will be described in conjunction with exemplary embodiments and methods of use, it will be understood by those skilled in the art that such description is not intended to limit the scope of the present disclosure, and various alternations, modifications and equivalents may be made therein without departing from the spirit and scope of the invention as defined by the appended claims.

### BRIEF DESCRIPTION OF THE DRAWINGS

The accompanying drawings, which are included to provide a further understanding of the invention and constitute a part of this specification, together with the embodiments, are therefore to be considered in all respects as illustrative and not restrictive. In addition, the drawings are merely illustrative, which are not drawn to scale.

FIG. 1 is a structural diagram of a known light-emitting diode.

FIG. 2 is a structural diagram of a second known light-emitting diode.

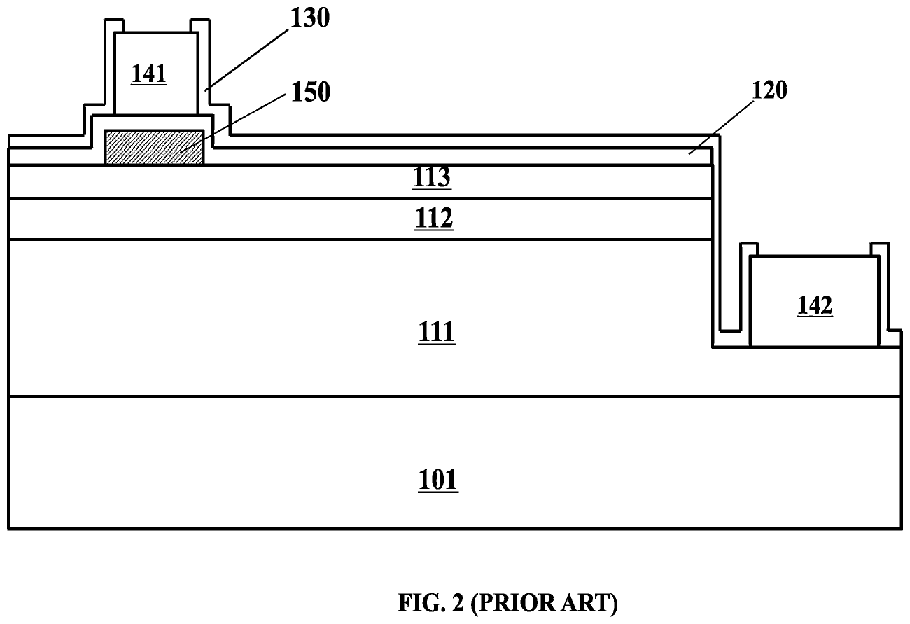

FIG. 3 is a structural diagram of the light-emitting diode provided in embodiment 1.

FIG. 4 is a top view of the light-emitting diode provided in embodiment 1.

FIG. 5 is a mask diagram for producing the light-emitting diode provided in embodiment 2.

FIG. 6 is a sectional diagram of a first step in fabricating the light-emitting diode according to embodiment 2.

FIG. 7 is a sectional diagram of a second step in fabricating the light-emitting diode according to embodiment 2.

FIG. 8 is a sectional diagram of a third step in fabricating the light-emitting diode according to embodiment 2.

FIG. 9 is a structural diagram of the light-emitting diode provided in embodiment 3.

FIG. 10 is a top plan view of the light-emitting diode according to embodiment 4.

FIG. 11 is a structural diagram of the light-emitting diode according to embodiment 4.

FIG. 12 is a top plan view of the light-emitting diode according to embodiment 5.

FIG. 13 is a structural diagram of the light-emitting diode according to embodiment 5.

FIG. 14 is a top plan view of the light-emitting diode according to embodiment 6.

FIG. 15 is a structural diagram of the light-emitting diode according to embodiment

6.

FIG. 16 is a top plan view of the light-emitting diode according to embodiment 7.

FIG. 17 is a structural diagram of the light-emitting diode according to embodiment 7.

FIG. 18 is a structural diagram of the light-emitting diode provided in embodiment 8.

FIG. 19 illustrates a reflective effect of the interface between the electrode extension branch of the light-emitting diode shown in FIG. 18 and the protective layer.

FIG. 20 illustrates a light extraction effect of the electrode extension branch of the light-emitting diode shown in FIG. 18.

FIG. 21 is a structural diagram of the light-emitting diode provided in embodiment 9.

FIG. 22 is a structural diagram of the light-emitting diode provided in embodiment 10.

FIG. 23 is a structural diagram of the light-emitting diode provided in embodiment 11.

FIG. 24 is a structural diagram of the light-emitting diode provided in embodiment 12.

FIG. 25 is a structural diagram of the light-emitting diode provided in embodiment 13.

FIG. 26 is a structural diagram of the light-emitting diode provided in embodiment 14.

FIG. 27 is a structural diagram of the light-emitting diode provided in embodiment 15.

FIG. 28 is a structural diagram of the light-emitting diode provided in embodiment 16.

FIG. 29 is a structural diagram of the light-emitting diode provided in embodiment 17.

FIG. 30 is a structural diagram of the light-emitting diode provided in embodiment 18.

FIG. 31 is a structural diagram of the light-emitting diode provided in embodiment 19.

### DETAILED DESCRIPTION

The embodiments of the present disclosure will be described in detail with reference to the accompanying drawings and examples, to help understand and practice the disclosed embodiments, regarding how to solve technical problems using technical approaches for achieving the technical effects. It should be noted that the embodiments and their features described in this disclosure may be combined with each other and such technical proposals are deemed to be within the scope of this disclosure without departing from the spirit of this invention.

### Embodiment 1

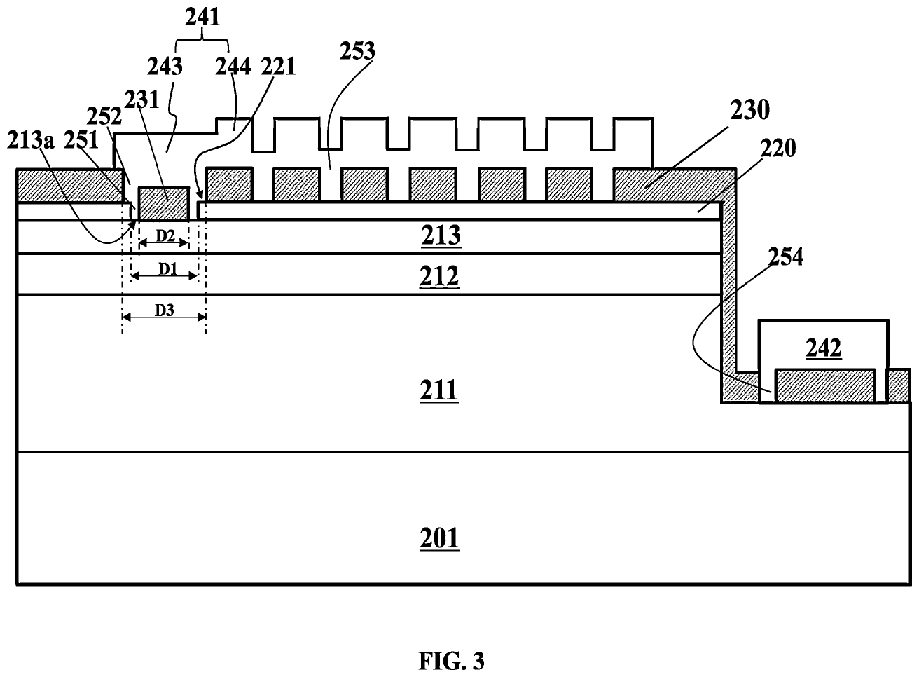

FIG. 3 shows a light-emitting diode, comprising: a substrate 201, a N-type layer 211, a light-emitting layer 212, a P-type layer 213, a transparent conductive layer 220, a semiconductor protective layer 230, a first electrode 241, and a second electrode 242.

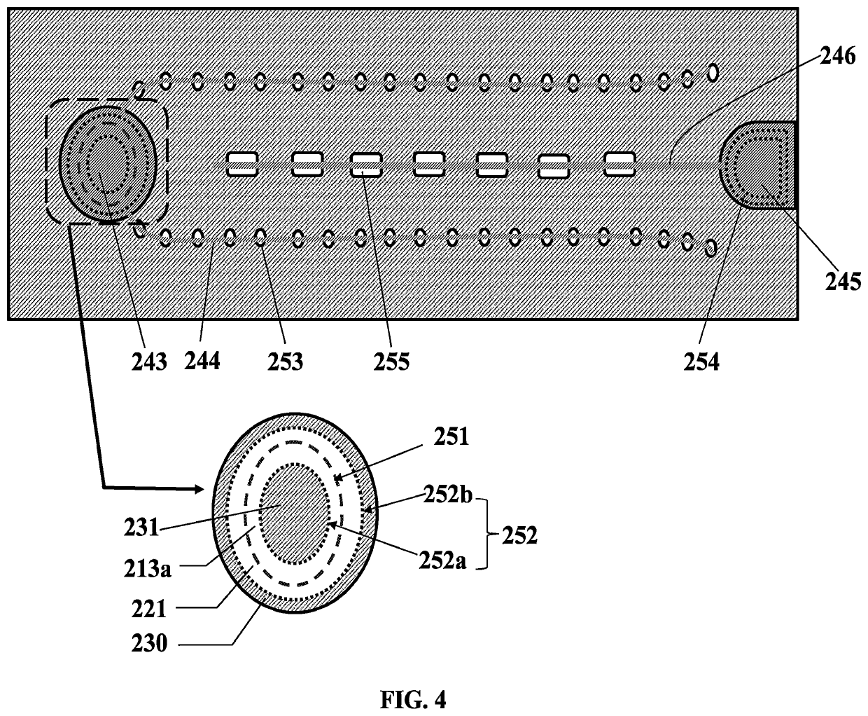

Specifically, the substrate 201 can be, but without limitation to, any of the following: sapphire, Aluminium nitride, gallium nitride, silicon and silicon carbide, having plain or patterned surface; the N-type layer 211 is formed on the substrate 201; the light emitting layer 212 is formed on the N-type layer 211; the P-type layer 213 is formed on the light emitting layer 212; the transparent conductive layer 220 is formed on the P-type layer 213; the semiconductor protective layer 230 is formed on the transparent conductive layer 220; the first electrode 241 and the second electrode 242 are formed on the semiconductor protective layer 230. FIG. 4 shows a top view of the light-emitting diode of FIG. 3, wherein the first electrode 241 includes a pad 243 and an extension branch 244, while the second electrode 242 includes a pad 245 and an extension branch 246.

With reference to FIG. 3 and FIG. 4, the transparent conductive layer 220 has one or more first openings 251 at the location corresponding to the pad 243; the semiconductor protective layer 230 has a second opening 252 at the location corresponding to pad 243, and some third openings 253 at the location corresponding to extension branch 244 to expose the transparent conductive layer 220. Specifically, the second opening 252 is of an annular structure, the inner ring 252a of the second opening 252 has a diameter D2 smaller than the diameter D1 of the first opening 252, while outer ring 252b has a diameter D3 greater than the diameter D1 of the first opening 251. FIG. 4 also shows local amplification details of the pad area prior to formation of the first electrode; according to FIG. 4, surfaces exposed in the pad area of the first electrode at this time, from outside to the inside, are the semiconductor protective layer 230, the transparent conductive layer 221, the P-type layer 213a and the semiconductor protective layer 231; the pad 243 formed on at this time of the first electrode can have simultaneous contact with the P-type layer 213a, the transparent conductive layer 221 and the semiconductor protective layer 230. As such, the semiconductor protective layer 231 is provided as a current blocking layer under the pad 243 of the first electrode; when upon electrification, most current is injected into the transparent conductive layer 220 through third opening 253 by the extension branch 244, and a small amount of current is injected into transparent conductive layer 220 via a portion 221 of the transparent conductive layer 220 in contact with the pad 243, then is expanded in the transparent conductive layer 220 to be implanted into the light-emitting epitaxial layer.

The semiconductor protective layer 230 can be made of SiO2, Si3N4, Al2O3 or TiO2, and SiO2 is selected in this implementation. In this embodiment, the semiconductor protective layer 230 functions to protect the light-emitting diode surface on one hand, and to serve as a current blocking layer on the other hand, so as to inhibit excessive injection of current below the electrode and enhance current dispersion of the transparent conductive layer. Therefore, considering requirements of both functions, the semiconductor protective layer has thickness d of λ/4n×(2k−1), where λ is the luminous wavelength of the light-emitting layer 212, n is the refractive index of the protective layer, k is a natural number above 1, preferably 2-3, corresponding thickness is better between 150 nm-500 nm; or otherwise excessively small thickness will adversely affect the performance as a current blocking and protective layer, and excessively large thickness will cause additional light loss due to light absorption by the material.

In this embodiment, the epitaxial laminate forms a mesa 210 and a series of through holes 256 running through the P-type layer 213 and the light-emitting layer 212 to exposing partial surface of the N-type layer 211; the semiconductor protective layer 230 covers the side wall of through hole 256, the side wall between transparent conductive layer 220 and the mesa 210, and the surface of the mesa 210; a fourth opening 254 of a annular form is reserved at the mesa 210; the second electrode 242 is made on the surface of semiconductor protective layer 230, where the pad 245 has contact with the N-type layer 211 via the fourth opening 254, and the extension branch 246 has contact with N-type layer 211 via the through hole 256.

Further, the semiconductor protective layer 230 in this embodiment is preferably made of transparent medium, and can form an omni-reflector with the electrode extension branch, so as to improve the reflective efficiency of the metal-medium interface and reduce light loss due to absorption by the metal.

In this embodiment, the protective layer 230 light-emitting diode functions to protect the light-emitting diode from damage on one hand, and to serve directly as a current blocking layer on the other hand, so as to inhibit excessive current injection below the electrode and improve current dispersion of the transparent conductive layer. Further, the first electrode has direct contact with the semiconductor layer in the pad area to effectively improve the adhesion between the electrode and the epitaxial layer and reduce the risk of the electrode separating from the contact surface upon routing. The pad of the first electrode is designed with steps at multiple locations to effectively buffer impact of wire bonding and to reduce impact and damage to the pad of the first electrode during wire bonding; the extension of the first electrode is provided on the protective layer, and gets in contact with the transparent conductive layer via through holes, so that the extension branch of the first electrode has an undulated upper surface, thereby increasing the angle of light emission at the extension strip, and improving the light extraction efficiency.

### Embodiment 2

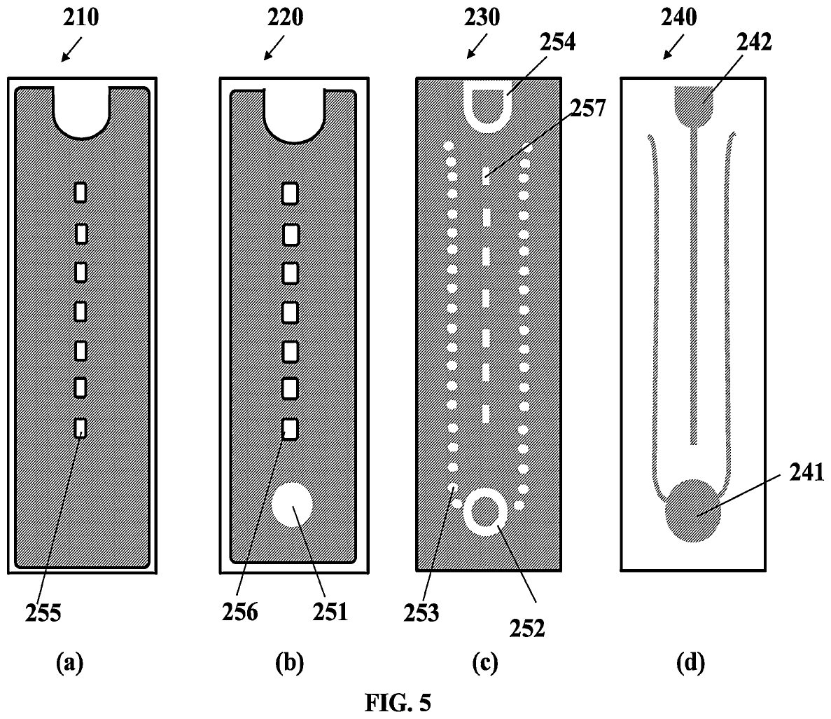

This embodiment discloses a light-emitting diode production method, mainly including four procedures, i.e. MESA etching, transparent conductive layer (such as ITO) production, electrode production and protective layer production. FIG. 5 shows four mask patterns involved in each of the four procedures. A brief description is made below in combination with FIG. 5-8.

First, provide a epitaxial laminate structure, generally comprising a substrate 201, a N-type layer 211, a light-emitting layer 212, a P-type layer 213.

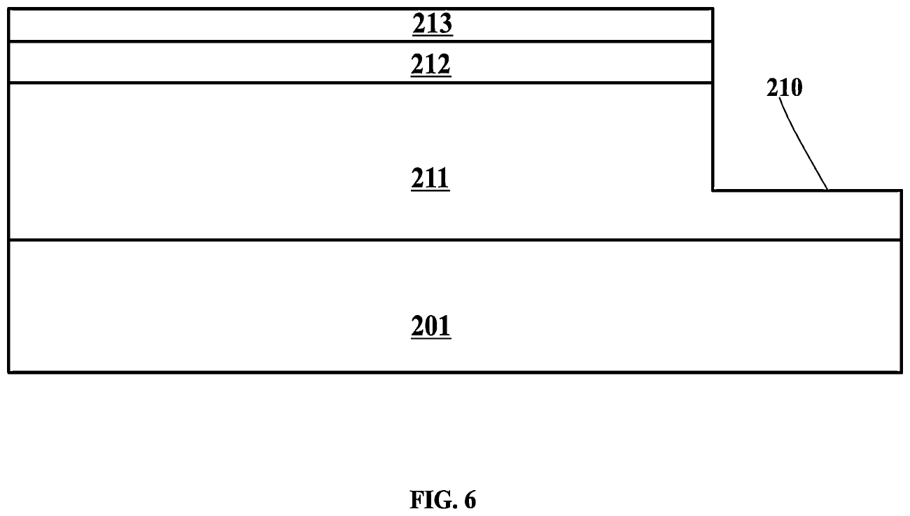

Then, define a first electrode area and a second electrode area on the surface of the epitaxial laminate with reference to the pattern shown in FIG. 5, panel (a); remove the blank areas to form mesa 210 of the second electrode and a series of through holes 255, as shown in FIG. 6;

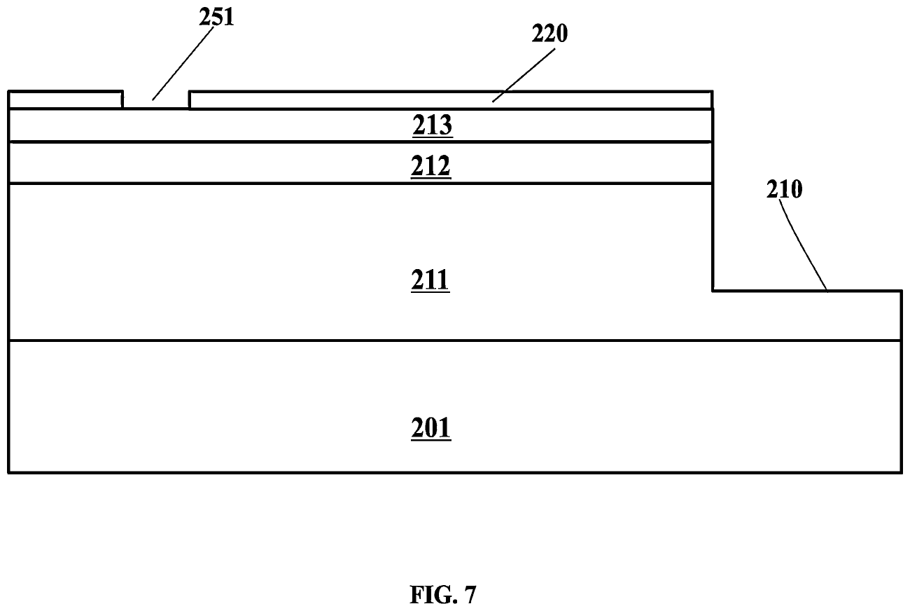

Next, make the transparent conductive layer 220 on the P-type layer 213 with reference to the pattern shown in FIG. 5, panel (b); remove the blank areas by etching to form opening 251 in the pad area of the first electrode and opening 256 at the location corresponding to through hole 255, as shown in FIG. 7;

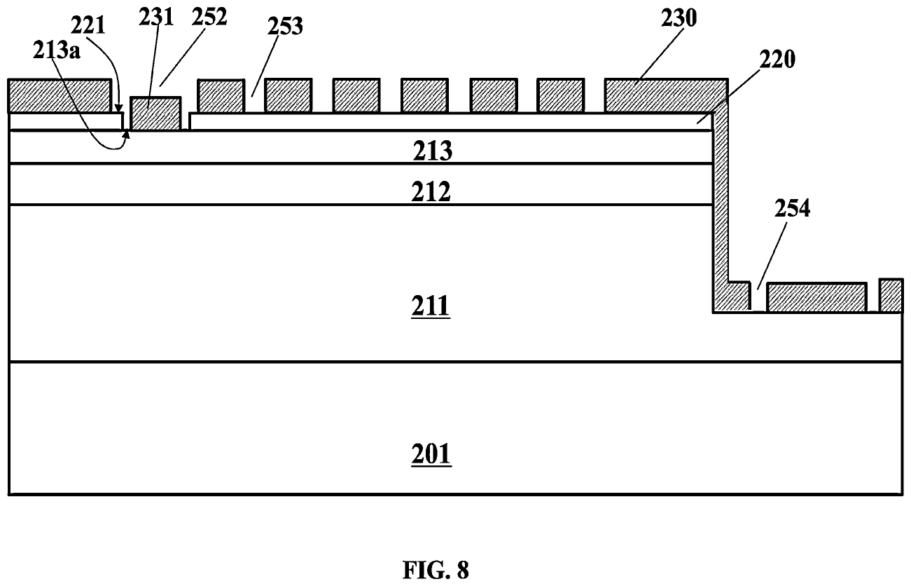

Next, make the semiconductor protective layer 230 on the transparent conductive layer 220 with reference to the pattern shown in FIG. 5, panel (c), and remove the blank areas by etching to form opening 252 in the pad area of the first electrode area, opening 253 in the extended area of the first electrode area, opening 254 on mesa 210, and opening 257 in the extended area of the second electrode. So that the protective layer 230 simultaneously covers the side wall of through hole 256, the side wall between the transparent conductive layer 220 and the mesa 210, and the surface of the mesa 210. Preferably, the opening 252 is of annular structure and has diameter D2 of inner ring 252a smaller than diameter D1 of the opening 252, and diameter D3 of outer ring 252b greater than diameter D1 of the opening 251. thereby, surfaces exposed in the pad area of the first electrode sequentially from outside to inside are the semiconductor protective layer 230, the transparent conductive layer 221, the P-type layer 213a and the semiconductor protective layer 231, as shown in FIG. 8;

Next, make first electrode 241 and second electrode 242 on the semiconductor protective layer 230 with reference to the pattern shown in FIG. 5, panel (d), wherein the pad 243 of first electrode 241 has simultaneous contact with the P-type layer, the transparent conductive layer and the protective layer.

It should be specially noted that the shape and/or the size of opening 252 are not limited to the description above, and the opening 252 can be designed to a non-circular structure. For example, in some implementations, the first electrode has no protective layer 231 below the pad center, and the pad center has direct contact with P-type layer 213. In other implementations, opening 252 can also be designed to be a structure which has a series antennae distributing around the pad area to expose the transparent conductive layer but no opening structure formed in the pad area, in such case, all the pad part of the first electrode is formed on the protective layer 230, and can be connected with metal leads to the antennae.

### Embodiment 3

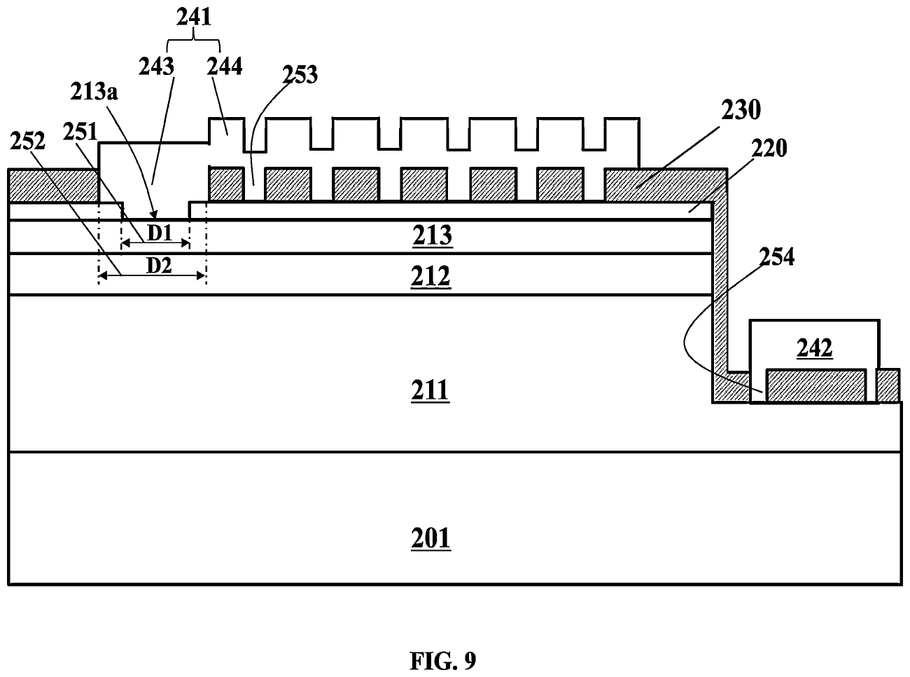

FIG. 9 shows a structural diagram of a second light-emitting diode. What this embodiment differs from EMBODIMENT 1 is that in the structure of the light-emitting diode provided in this embodiment, diameter D1 of second opening 252 is greater than or equal to diameter D1 of the first opening 251, in this case, the pad 243 has no semiconductor protective layer below and is in direct contact with P-type layer 213, so that the pad 243 is in direct contact with the semiconductor layer. Due to the electrode has good adhesion to the GaN layer which can reduce the risk of the first electrode being separated from the adhesion interface upon routing.

### Embodiment 4

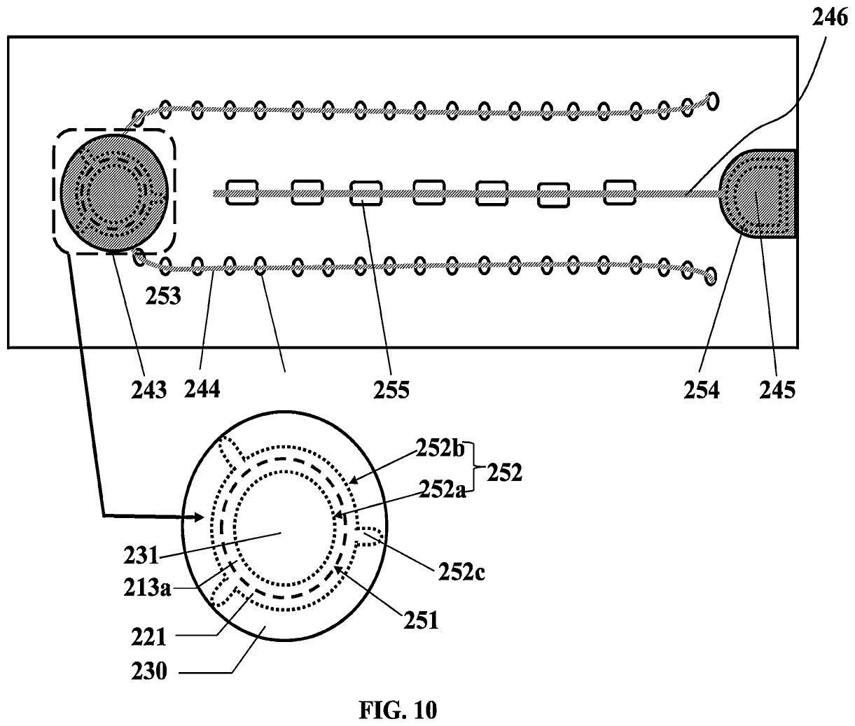

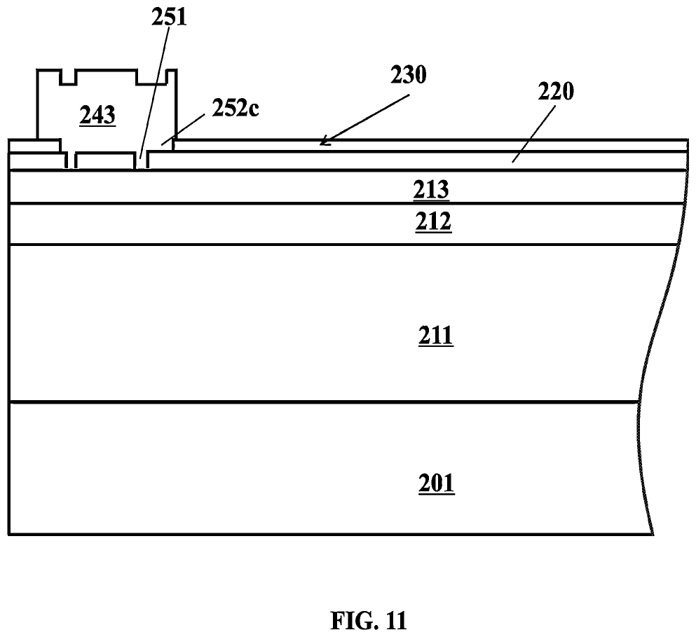

FIG. 10-11 show a structural diagram of a third light-emitting diode. What this embodiment differs from EMBODIMENT 1 is that in the structure of the light-emitting diode provided in this embodiment, the second opening 252 is of annular form and has at least one antenna 252c extending away from the pad area, the number of 252c is 1-20. Pad part 243 of the first electrode gets in contact with the transparent conductive layer via antenna 252c, thereby increasing the contact area between the pad of the first electrode and the transparent conductive layer and facilitating current dispersion, so as to relieve current congestion on the pad area and the extended area of the first electrode, and reduce the risk of the electrode metal being extracted and burnt.

### Embodiment 5

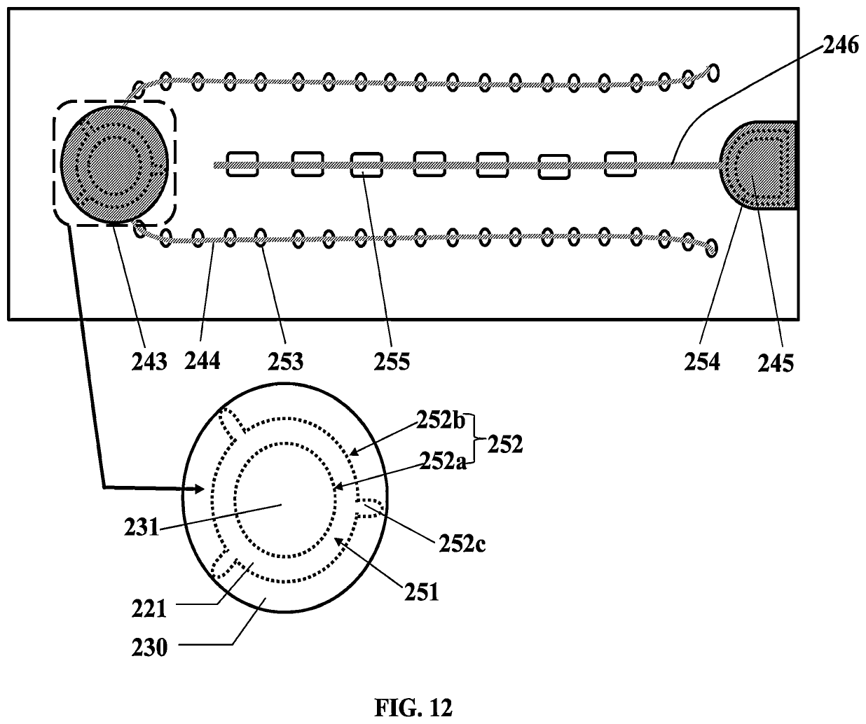

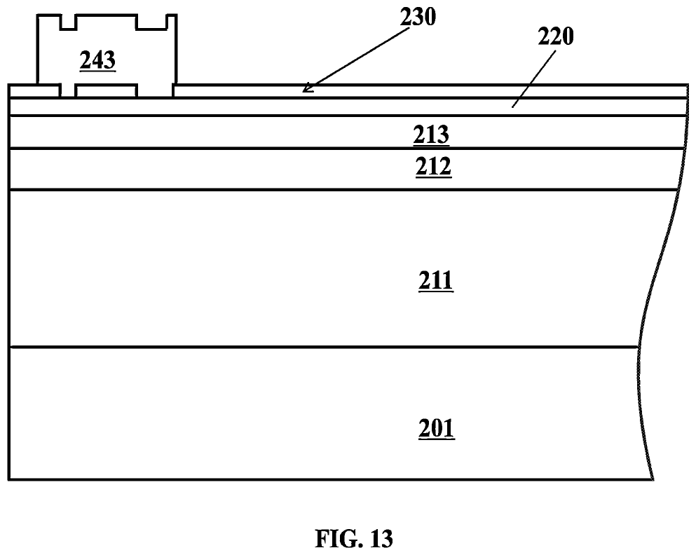

FIG. 12-13 show a structural diagram of a fourth light-emitting diode. What this embodiment differs from EMBODIMENT 4 is that in the structure of the light-emitting diode provided in this embodiment, the transparent conductive layer 220 does not form an opening in the pad area of the first electrode, and the pad 243 of the first electrode has direct contact with transparent conductive layer 221 and the protective layer 230.

### Embodiment 6

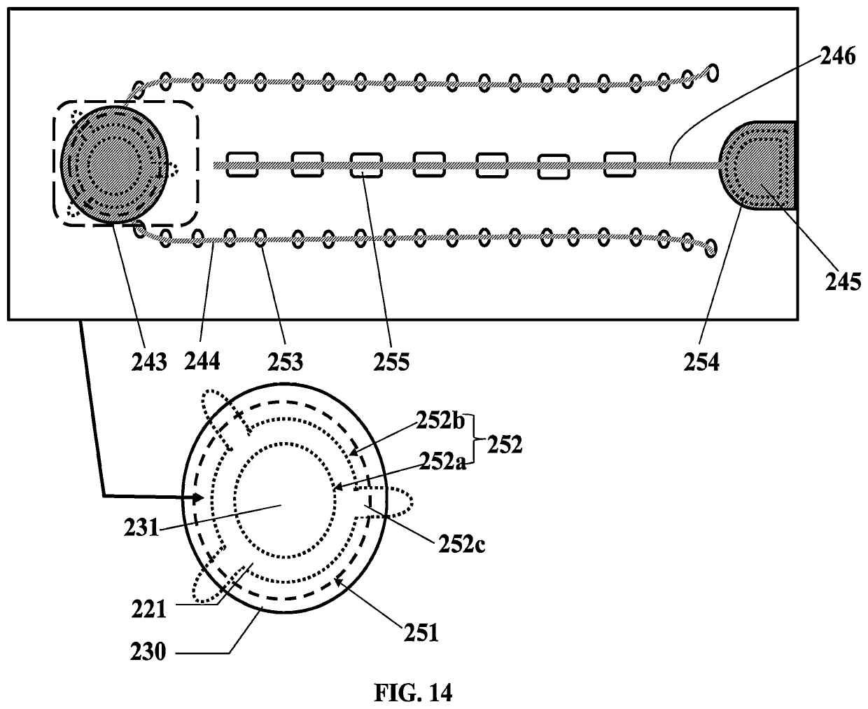

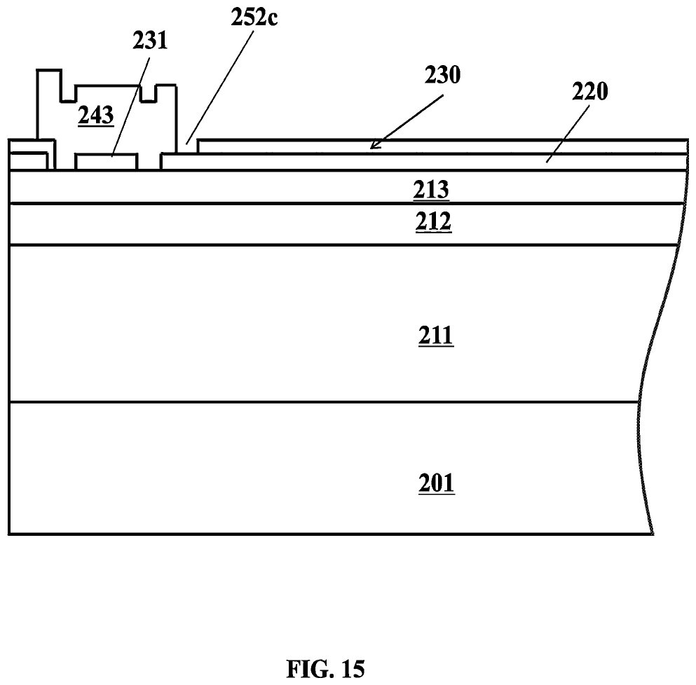

FIG. 14-15 show the structural diagram of a fifth light-emitting diode. What this embodiment differs from EMBODIMENT 4 is that in the structure of the light-emitting diode provided in this embodiment, transparent conductive layer 220 forms first opening 251 at the location corresponding to pad 243 of the first electrode, and first opening 251 lies between the second opening periphery 252b and the antenna 252c, while the antenna 252c of second opening 252 extends beyond the pad 243 of the first electrode. The pad 243 of the first electrode has contact with the transparent conductive layer via antenna 252c from first opening 251, thereby reducing the contact area between the pad part of the first electrode and the transparent conductive layer and lowering risk of the transparent conductive layer being broken during wire soldering. Besides, steps are designed at multiple locations to effectively relieve impact from wire soldering, as well as to reduce impact and damage to the pad of the first electrode during wire soldering.

### Embodiment 7

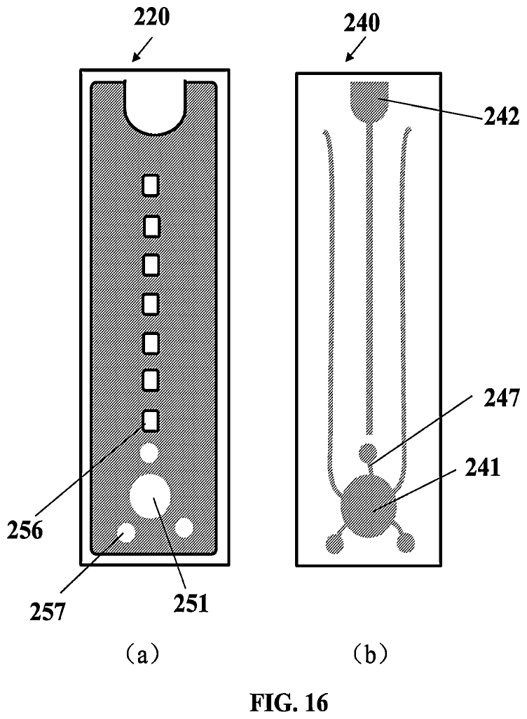

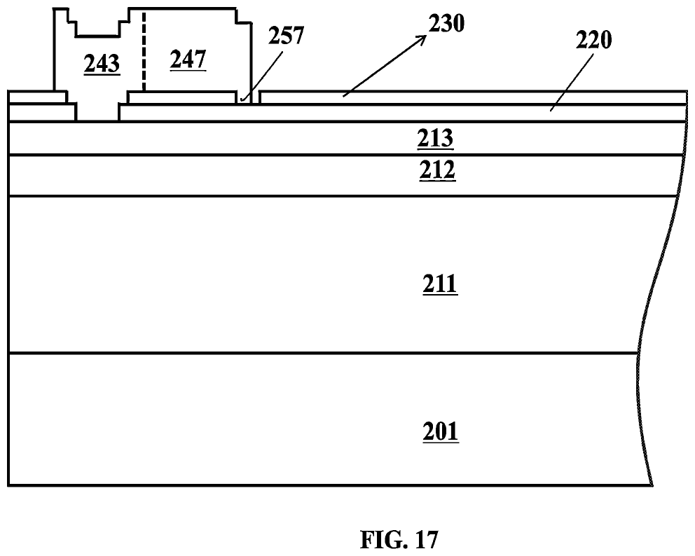

FIG. 16-17 show the structural diagram of a sixth light-emitting diode. FIG. 16 shows the patterns of semiconductor layer 230 and electrodes. What this embodiment differs from EMBODIMENT 1 is that in the structure of the light-emitting diode provided in this embodiment, semiconductor protective layer 230 forms a series of opening 252c around the pad area of the first electrode, transparent conductive layer 220 is exposed, and the pad part of the first electrode leads out antenna 247 to opening 257; the number of antennae 252c is 1-20.

It should be specially noted that in some varied embodiments, it is unnecessary for transparent conductive layer 220 to form an opening structure in the pad area; in other embodiments, neither transparent conductive layer 220 nor semiconductor protective layer 230 forms opening in the pad area of the first electrode, in which case pad part 243 of the first electrode is fully formed on the protective layer without contact with transparent conductive layer 220 or P-type layer 213.

### Embodiment 8

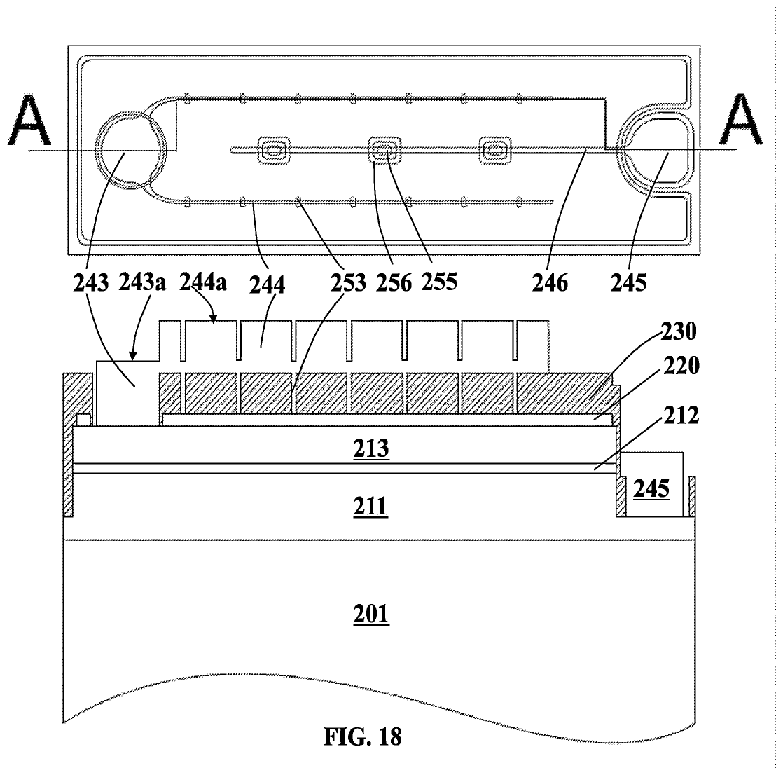

FIG. 18 shows the top view and A-A sectional view of a seventh light-emitting diode. What this embodiment differs from EMBODIMENT 1 is that in the structure of the light-emitting diode provided in this embodiment, opening 251 of transparent conductive layer 220 in the pad area of the first electrode has the same size with opening 252 of the semiconductor protective layer in the pad area of the first electrode. In this embodiment, protective layer 220 has thickness of preferably above 200 nm; according to the A-A sectional view shown in FIG. 18, upper surface 243 of the pad part of the first electrode is obviously lower than upper surface 244a of extension branch 244 at the high position.

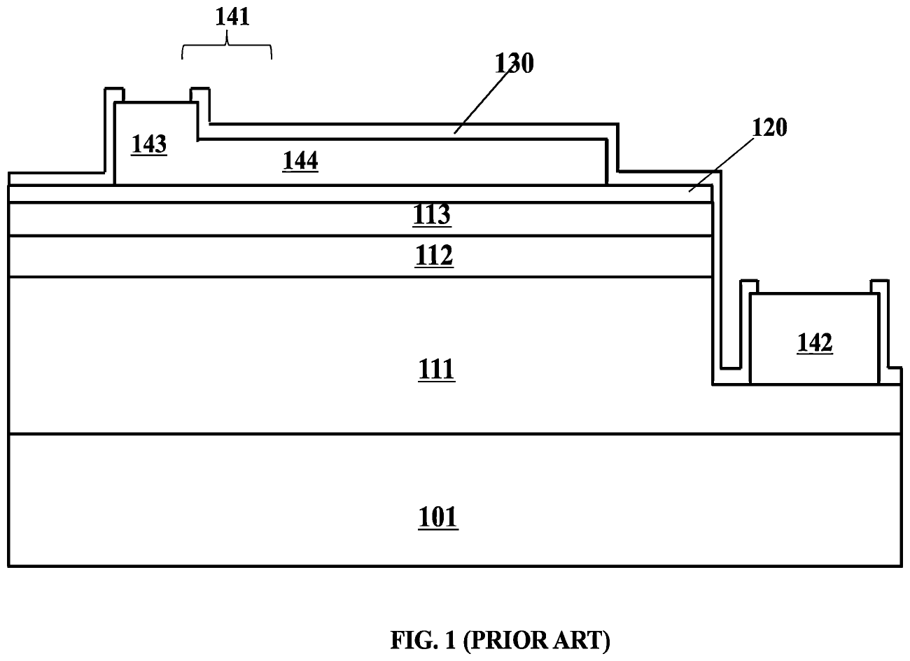

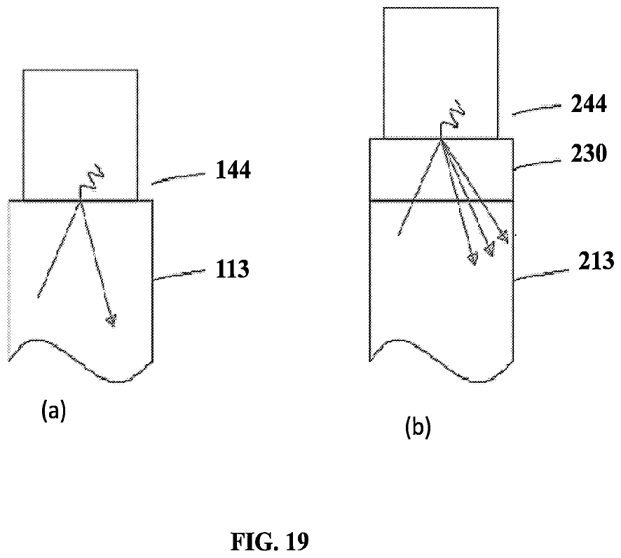

In the structure of the light-emitting diode shown in FIG. 1, secondary light of light emitted from the light-emitting layer as reflected by the bottom or side wall will, when arriving at the interface between extension branch 144 of P electrode and P-type layer, be absorbed by the metal and incur loss of light extraction efficiency; meanwhile, light after multiple reflections by N electrode and the bottom of N electrode will, when arriving at the interface between extension branch 144 of P electrode and P-type layer, also be absorbed by the metal and incur loss of light extraction efficiency. In the embodiment, protective layer 230 is added in some areas right below extension branch 244 of the first electrode, and for the protective layer, transparent medium is preferably used; protective layer 230 can form an omni-directional reflector with extension branch 244 of the first electrode. FIG. 19 shows the reflection diagram of the electrode extension branch of the light-emitting diode provided in FIG. 1 and that shown in this embodiment. According to the figures, extension branch 244 and protective layer 220 in this embodiment form an omni-directional reflector, which may effectively improve the reflection efficiency of the metal-medium interface and reduce loss of light due to absorption by the metal.

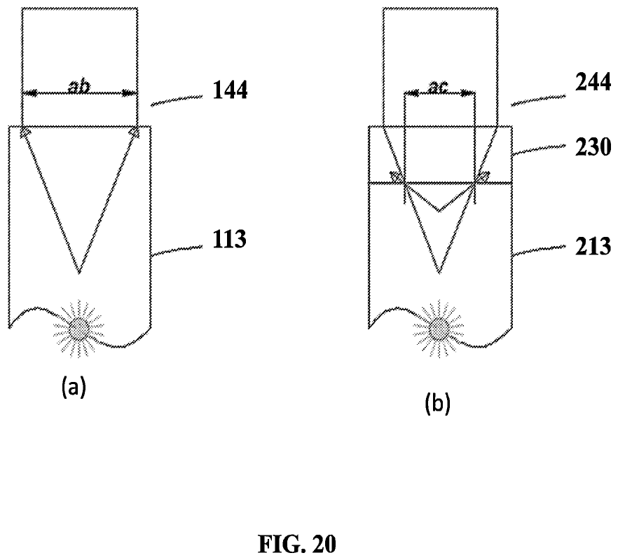

Further, the semiconductor protective layer 220 can be made of optically thinner material (relative to P-type semiconductor layer, such as GaN); in this case, the semiconductor protective layer has refractive effect; as shown in FIG. 20, if extension branch 244 of the first electrode has a sectional light blocking length ab, then in this embodiment where material with refractive effect is used for protective layer 230, extension branch 244 of the first electrode may have the actual light blocking length shortened to ac.

### Embodiment 9

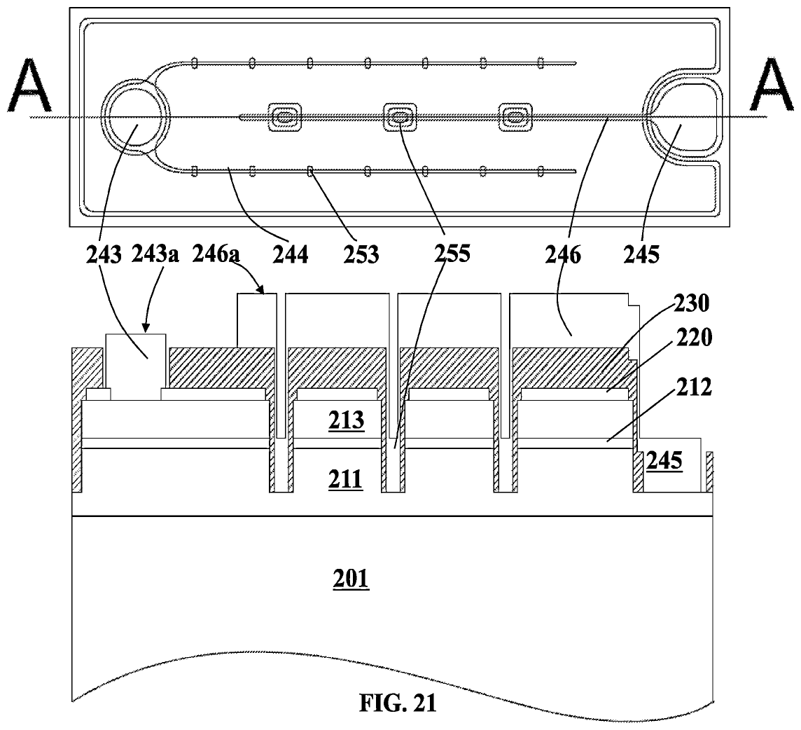

FIG. 21 shows the top view and A-A sectional view of an eighth light-emitting diode. The sectional view mainly shows pad part 243 of the first electrode and the specific structure of the second electrode. In this embodiment, opening 251 of transparent conductive layer 220 in the pad area of the first electrode has a smaller size than opening 252 of semiconductor protective layer 230 in the pad area of the first electrode, while the pad part of the first electrode has simultaneous contact with P-type layer 213 and surface of the transparent conductive layer.

In this embodiment, the epitaxial laminate forms a mesa and a series of through holes 255 running through P-type layer 213 and light-emitting layer 212; partial surface of N-type layer 211 is exposed; semiconductor protective layer 230 covers the side wall of through holes 255, the side wall between transparent conductive layer 220 and the mesa, and surface of the mesa; a fourth opening is reserved at the mesa; second electrode 242 is made on the surface of semiconductor protective layer 230; pad part 245 has contact with the N-type layer through the fourth opening, while extension branch 246 has contact with the N-type layer via through holes 255.

Specifically, extension branch 246 of the second electrode is located in the middle of the chip, and has contact with the N-type layer via several through holes 255; extension branch 246 in areas not connected by through holes has upper surface higher than the upper surface of pad 243 of the first electrode, with the height difference ranging from 50 nm-500 nm; the said height difference is recommended but not restrictive; extension branch 246 of the first electrode may terminate at the shortest through hole covered, or properly extend, but should never have direct contact with the pad of the first electrode, as shown in FIG. 21.

In this embodiment, extension branch 246 of the second electrode forms an omni-directional reflector with the protective layer below, so as to improve the reflective efficiency of the metal-medium interface and reduce light loss due to absorption by the metal. Similarly, the protective layer can be made of optically thinner medium with refractive effect, thereby effectively reducing the light blocking area of the extension branch of the second electrode. For the principle, refer to FIG. 20 of EMBODIMENT 8.

Further, at the extension branch bottom of the second electrode are through holes 255 provided on the P-type layer and the light emitting layer, enabling a waved extension branch, an increased effective area of ITO and higher efficiency of light extraction.

### Embodiment 10

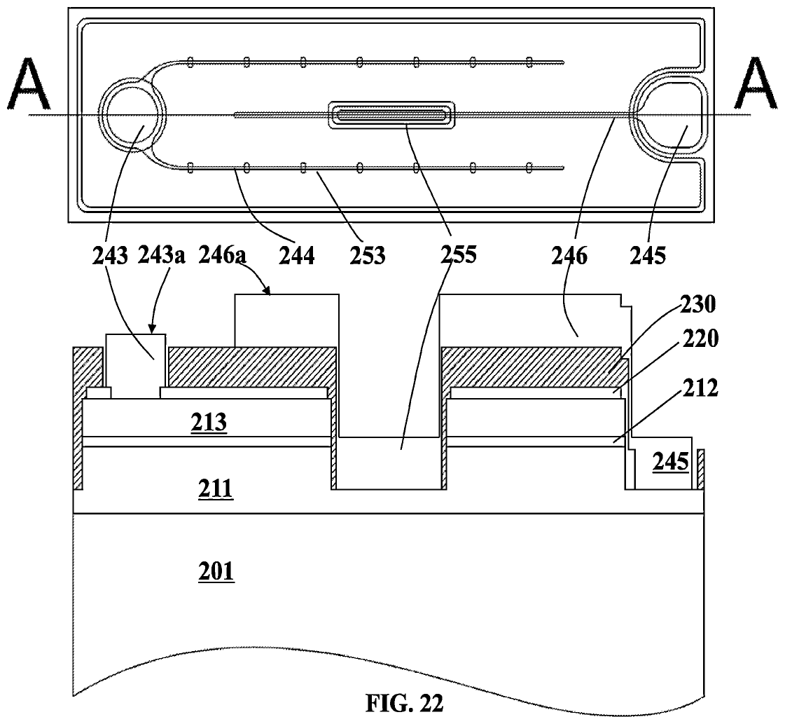

FIG. 22 shows the top view and A-A sectional view of a ninth light-emitting diode, wherein the sectional view mainly shows pad part 243 of the first electrode and the specific structure of the second electrode. What this embodiment differs from EMBODIMENT 9 is that in this embodiment extension branch 246 of the second electrode gets in contact with the N-type layer via a strip opening.

### Embodiment 11

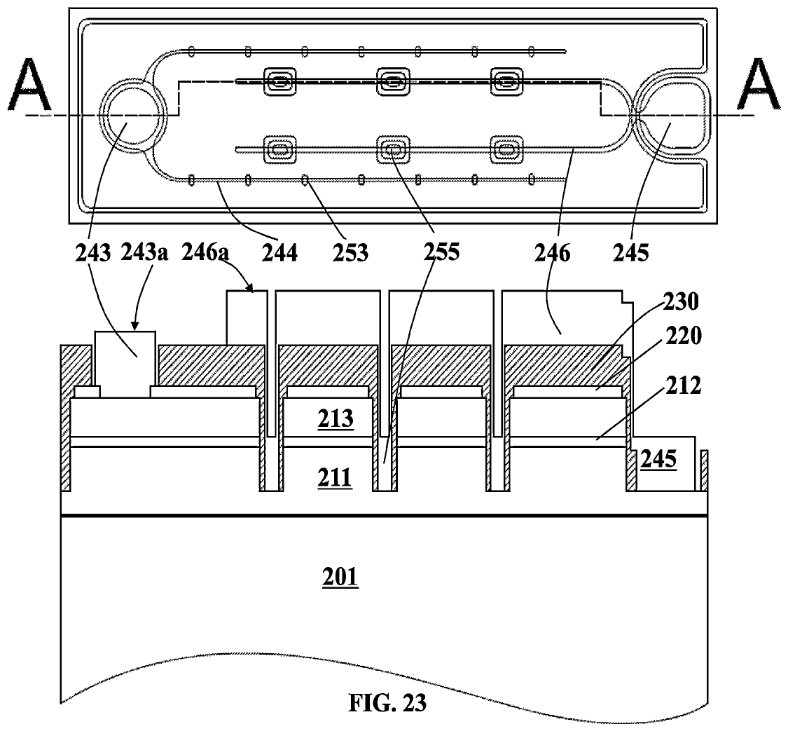

FIG. 23 shows the top view and A-A sectional view of a tenth light-emitting diode, wherein the sectional view mainly shows pad part 243 of the first electrode and the specific structure of the second electrode. What this embodiment differs from EMBODIMENT 9 is that in this embodiment, extension branch 246 of the second electrode has a double-row structure, as shown in the figure.

### Embodiment 12

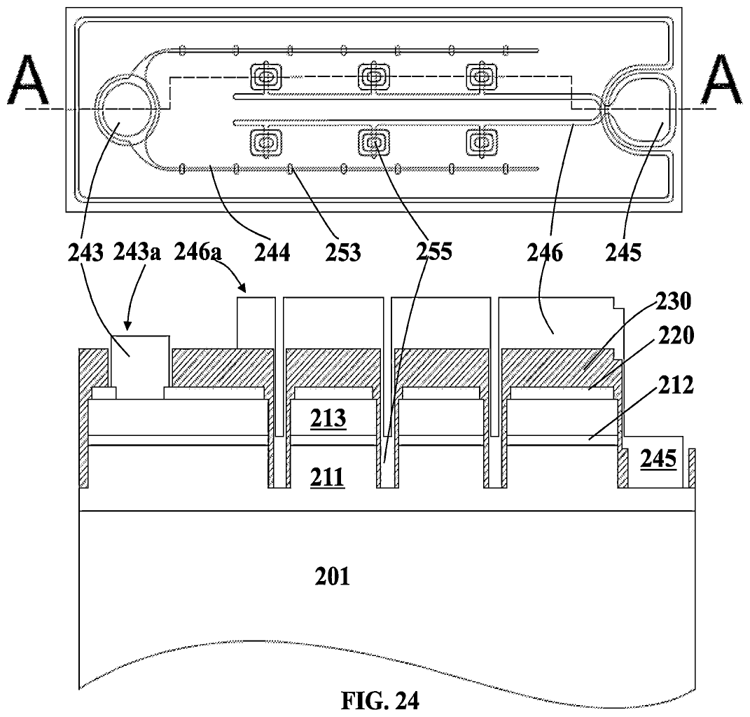

FIG. 24 shows the top view and A-A sectional view of an eleventh light-emitting diode, wherein the sectional view mainly shows pad part 243 of the first electrode and the specific structure of the second electrode. What this embodiment differs from EMBODIMENT 9 is that in this embodiment, extension branch 246 of the second electrode has a double-row structure and normal interpolation, as shown in the figure.

### Embodiment 13

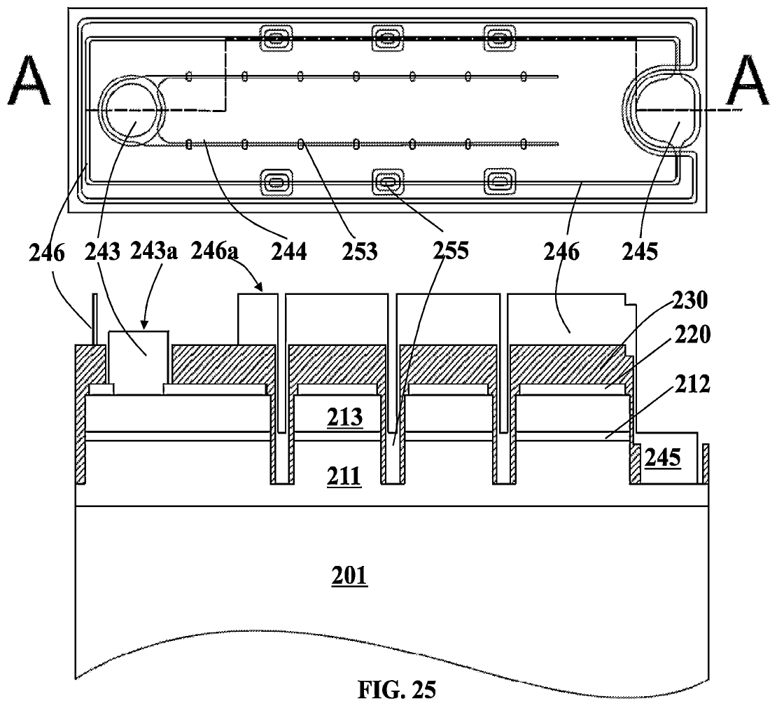

FIG. 25 shows the top view and A-A sectional view of a twelfth light-emitting diode, wherein the sectional view mainly shows pad part 243 of the first electrode and the specific structure of the second electrode. What this embodiment differs from EMBODIMENT 9 is that in this embodiment, extension branch 246 of the second electrode has a closed-loop structure, where extension branch 244 of the first electrode is located inside of extension branch 246 of the second electrode, as shown in the figure.

### Embodiment 14

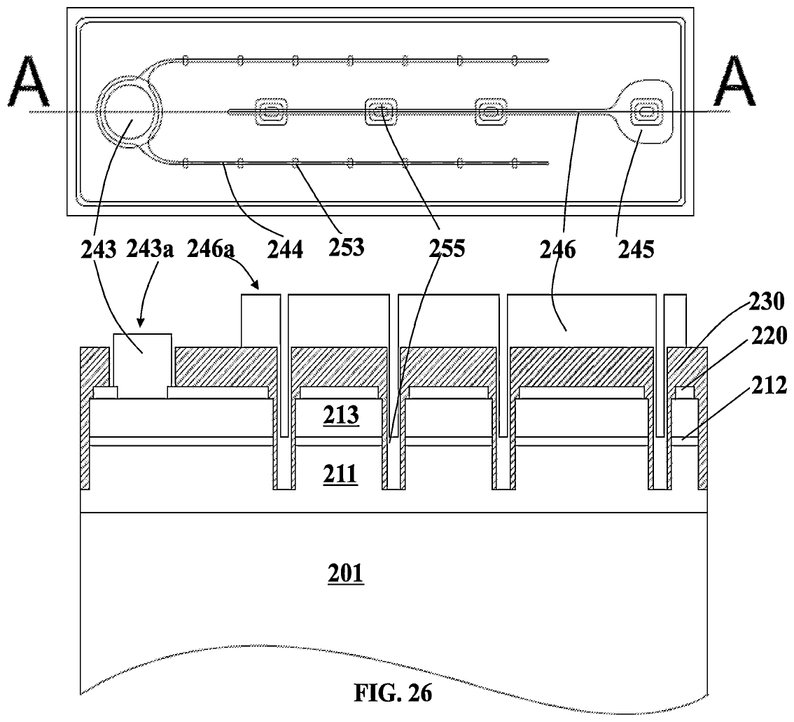

FIG. 26 shows the top view and A-A sectional view of a thirteenth light-emitting diode, wherein the sectional view mainly shows pad part 243 of the first electrode and the specific structure of the second electrode. What this embodiment differs from EMBODIMENT 9 is that in this embodiment, the epitaxial laminate does not form a mesa, while pad 245 and extension part 246 of the second electrode have contact with N-type layer 211 via through holes, in which case pad 245 and extension branch 246 of the second electrode generally have flush upper surface in non-through hole areas and both are higher than upper surface 243a of the first electrode, as shown in the figure.

Specifically, pad 245 of the second electrode may have one or more through holes provided below, where the proportion of single through hole diameter to pad diameter of the second electrode is preferably 1:2-1:20, and the total area of all through holes accounts for 2%-60% of the pad 245 of the second electrode; as the number of holes increase, the proportion of hole area also increases.

In this embodiment, only holes are made at the pad bottom of the second electrode for contact with N-type layer, which may effectively increase ITO area and facilitate current injection; meanwhile, most of the pad of the second electrode is on the protective layer, which is good for light extraction.

### Embodiment 15

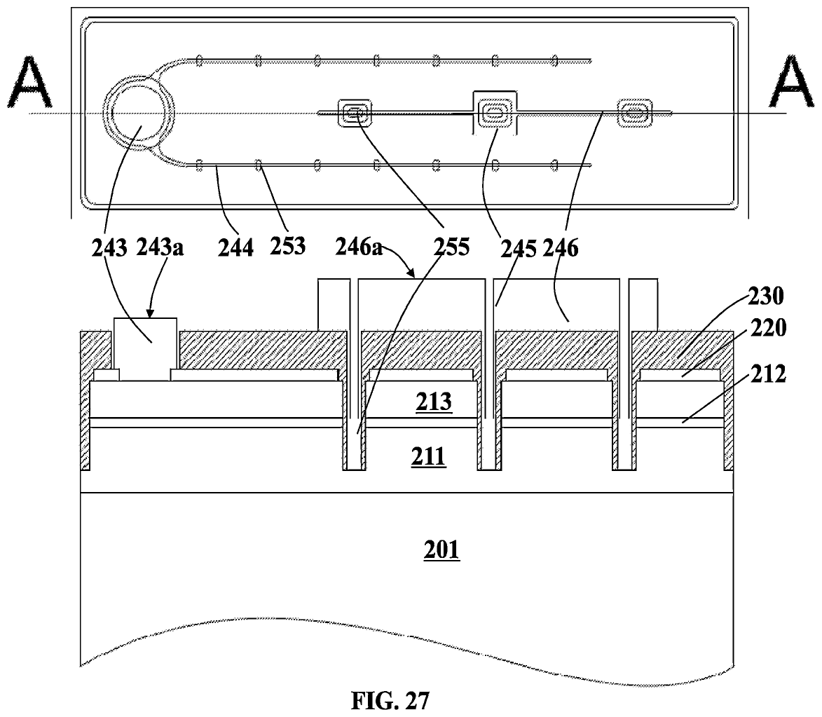

FIG. 27 shows the top view and A-A sectional view of a fourteenth light-emitting diode, wherein the sectional view mainly shows pad part 243 of the first electrode and the specific structure of the second electrode. What this embodiment differs from EMBODIMENT 15 is that in this embodiment, extension branch 246 of the second electrode has a bi-directional structure, specifically the second electrode being distributed in the central area of the chip, while pad 245 is located at the center and extension branch 246 extends in opposite directions from the pad, as shown in the figure.

### Embodiment 16

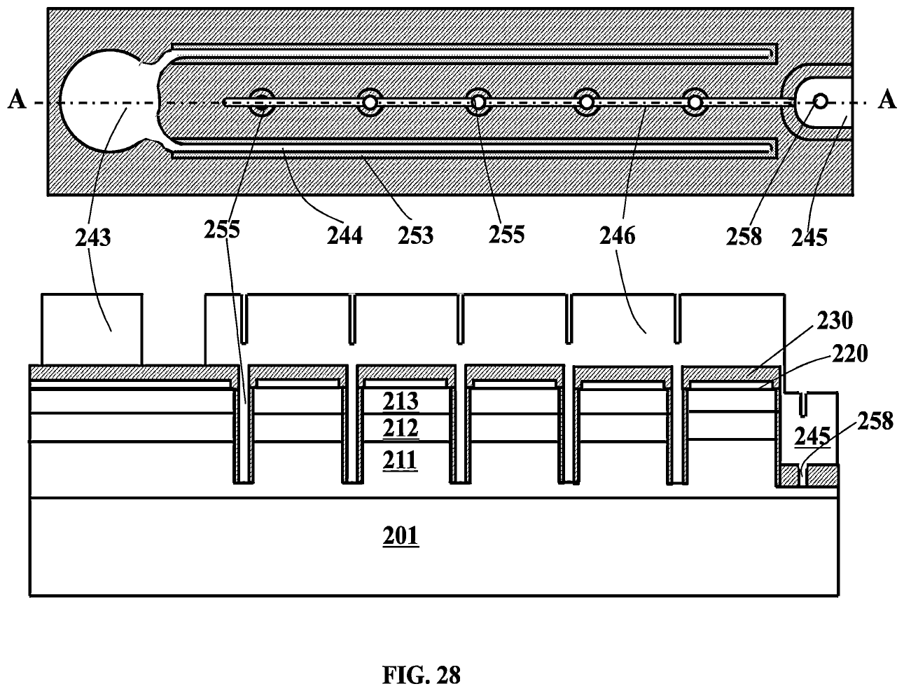

FIG. 28 shows the top view and A-A sectional view of a fifteenth light-emitting diode. What this embodiment differs from EMBODIMENT 1 is that in this embodiment, semiconductor protective layer 230 has generally full coverage of the light-emitting diode surface, only opening 253 (the part filled grey) being formed below extension branch 244 of the first electrode, through hole 258 formed below the pad of the second electrode, and through hole 255 formed below the extension branch of the second electrode. Therefore, the pad of the first electrode is directly formed on the protective layer, and injects into transparent conductive layer 220 via opening 253 below the extension branch.

In this embodiment, one through hole 258 is formed at the center right below pad 245 of the second electrode; the through hole has area accounting for 1%-5% of the pad area of the second electrode, and preferably has a size smaller than or equal to the size of through hole 255 below extension branch 246.

In this embodiment, pads of the first electrode and the second electrode are basically and directly formed on the protective layer. When SixOx is used for protective layer 230, it has good adhesion to the pad base layer (generally the reflective layer) to effectively reduce the risk of electrode separating from the adhesion surface; further, the extension branch bottom of the second electrode is designed with holes to increase the efficient lighting area and further to promote the light extraction efficiency of the chip.

### Embodiment 17

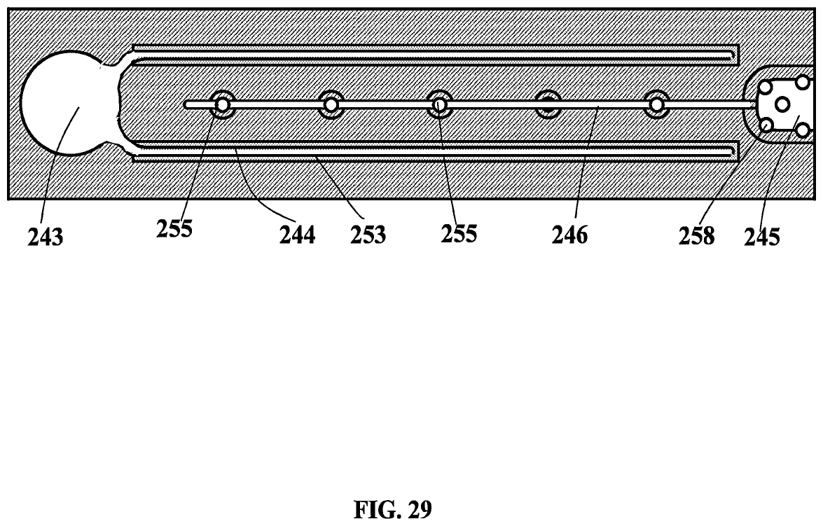

FIG. 29 shows the top view and A-A sectional view of a sixteenth light-emitting diode. What this embodiment differs from EMBODIMENT 16 is that in that in this embodiment, semiconductor protective layer 230 below pad 245 of the second electrode has multiple through holes 258 that are symmetrical about the center, the total area of the through holes preferably being 2%-50% of the pad area of the second electrode.

### Embodiment 18

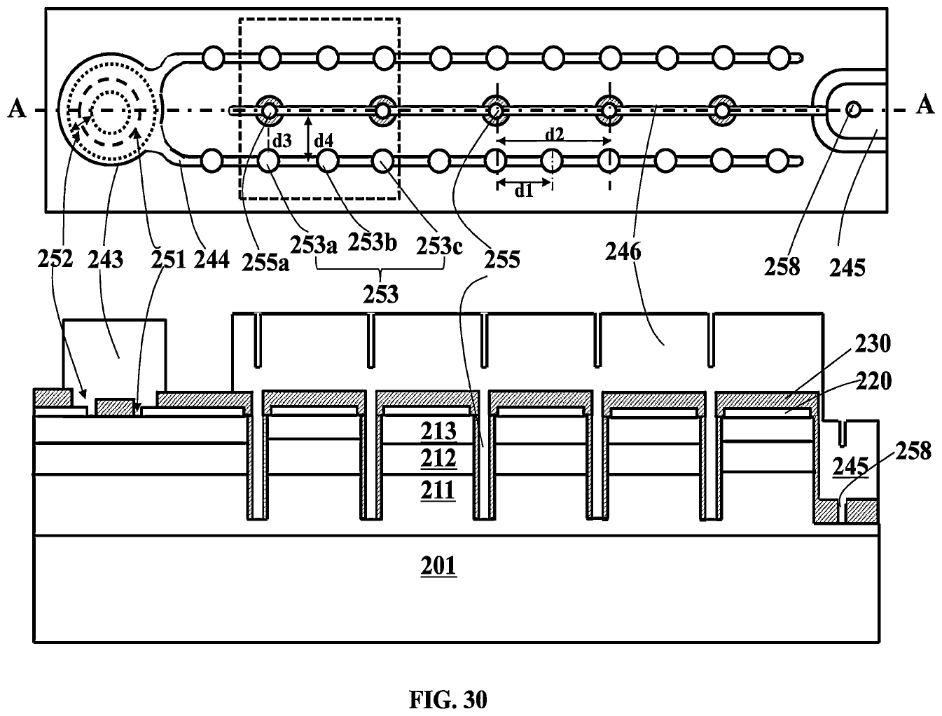

FIG. 30 shows the top view and A-A sectional view of a seventeenth light-emitting diode. What this embodiment differs from EMBODIMENT 16 is that in that in this embodiment, semiconductor protective layer 230 below pad 244 of the first electrode has a series of through holes 253 and exposes the surface of transparent conductive layer 220. Meanwhile, transparent conductive layer 220 below the pad of the first electrode and semiconductor protective layer 220 form openings 251 and 252, respectively, where opening 252 is of circular form; the circular inner ring has a diameter smaller than the diameter of opening 252, and outer ring has a diameter greater than the diameter of opening 251; pad 244 of the first electrode has simultaneous and stepped contact with surfaces of P-type layer 213, transparent conductive layer 220 and protective layer 230, while the sectional area reduces gradually from up to down, thereby effectively relieving impact of wire bonding and reducing impact and damage to the pad of the first electrode during wire bonding.

Specifically, the first electrode is composed of pad 243 and extension branch 244; the second electrode is composed of pad 245 and extension branch 246; extension 244 of the first electrode has contact with transparent conductive layer 220 via through holes 253; extension branch 246 of the second electrode has contact with N-type layer 211 via through holes 255; among three running through holes 253a-253c, at least one through hole 253a has distance d3 from the nearest through hole 255a not exceeding the distance d4 between extension branch 244 of the first electrode and extension branch 246 of the second electrode. In this embodiment, extension branch 244 of the first electrode and extension branch 246 of the second electrode are distributed in parallel; among three running through holes 253a-253c, at least one through hole 253a has connecting line to the nearest second through hole 255a perpendicular to the extension branch of the first electrode; distance d1 between two adjacent through holes 255 and distance d2 between two adjacent through holes 253 meet the following condition: d2≈2d1.

Though in the light-emitting diode shown in FIG. 30, pad 245 of the second electrode has contact with N-type layer 211 via through hole 258, and it should be understood that pad 253 of the second electrode is not limited to this arrangement. In other varied embodiments, through hole 258 below pad 246 of the second electrode can be changed to circular opening structure, as shown in FIG. 3; in other varied embodiments, pad 255 of the second electrode does not necessarily have direct contact with the N-type layer, namely: protective layer 230 fully covers the N-type layer below pad 255, and the second electrode gets contact with N-type layer 211 via through hole 255 below extension branch 246; in other varied embodiments, pad 255 of the second electrode may have direct contact with N-type layer 211, namely: protective layer 230 does not fully cover the N-type layer below pad 255.

### Embodiment 19

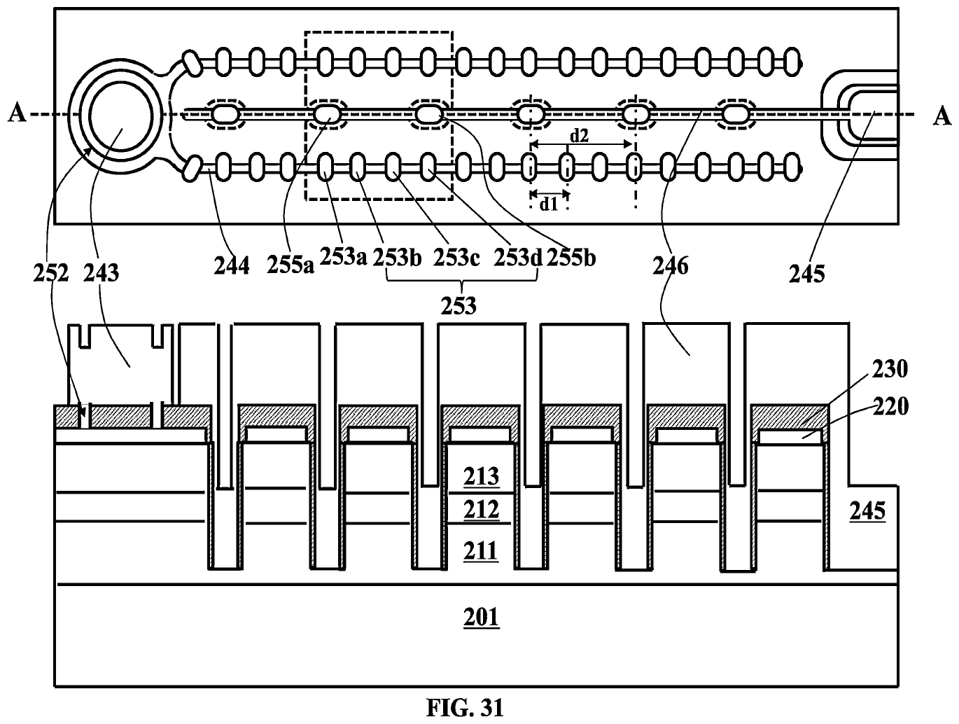

FIG. 31 shows the top view and A-A sectional view of an eighteenth light-emitting diode. What this embodiment differs from EMBODIMENT 16 is that in this embodiment, the protective layer below pad 244 of the first electrode has an opening form 252, and pad 245 of the second electrode is directly formed on the surface of the N-type layer without protective layer below.

In this embodiment, through hole 253 below extension branch 244 of the first electrode has a size slightly smaller than through hole 255 below the extension branch of the second electrode; among four running through holes 253a-253d, only the first and the last through holes, 253a and 253d, have corresponding through holes 255; in such case, the distance d1 between two adjacent through holes 255 and the distance d2 between two adjacent through holes 253 meet the following condition: d2≈3d1.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A light-emitting device, comprising:
a semiconductor structure including a first semiconductor layer, a light-emitting layer and a second semiconductor layer from up down, and said semiconductor structure having a mesa which exposes said second semiconductor layer;
a transparent conductive layer formed on the first semiconductor layer, and having a first opening to expose a portion of a surface of the first semiconductor layer;
a protective layer formed over said transparent conductive layer; and
a first electrode formed over least a portion of said protective layer, and having a pad portion and an extension connected to said pad portion;
wherein said protective layer having a second opening at a position corresponding to said pad portion to expose a portion of a surface of said first semiconductor layer and a portion of a surface of said transparent conductive layer, and said pad portion of said first electrode is in contact with both said first semiconductor layer and said transparent conductive layer through said second opening.

2. The light-emitting device of claim 1, wherein said second opening has a larger size than said first opening, and said pad portion of said first electrode is in contact with said first semiconductor layer and said transparent conductive layer.

3. The light-emitting device of claim 1, wherein said second opening is of annular form and has at least one antenna extending away from the pad portion, and said pad portion of said first electrode is in contact with said transparent conductive layer through said antenna.

4. The light-emitting device of claim 3, wherein said first opening having an edge between a periphery of said second opening and a periphery of said antenna.

5. The light-emitting device of claim 1, wherein said protective layer having a block structure disposed within said second opening, and said block structure being disposed within said first opening and having a gap with said transparent conductive layer, said pad portion of said first electrode is in contact with said first semiconductor layer through said gap.

6. The light-emitting device of claim 1, wherein said protective layer has a plurality of fifth openings around said second opening which expose said transparent conductive layer, and said first electrode comprising a plurality of antennas, said antennas being connected to a pad portion of said first electrode and being in contact with said transparent conductive layer through said fifth opening.

7. The light-emitting device of claim 1, wherein said protective layer having a at a position corresponding to said extension of said first electrode, said extension of said first electrode being in contact with said transparent conductive layer through said third opening.

8. The light-emitting device of claim 7, wherein said light-emitting device further comprising a second electrode provided on said protective layer and electrically connected to said second semiconductor layer, said second electrode including a second pad portion and a second extension, said second pad portion being disposed above said mesa.

9. The light-emitting device of claim 8, wherein said protective layer has a fourth opening which is at a position corresponding to said second pad portion, said second pad portion contacts said second semiconductor layer through said fourth opening, and said second pad portion has a distance to a edge of the fourth opening.

10. The light-emitting device of claim 8, wherein said second extension is in contact with said second semiconductor layer through a through-hole in the shape of a strip.

11. The light-emitting device of claim 8, wherein said protective layer has a series of spaced openings at positions corresponding to said second extension, and said second extension being in contact with said second semiconductor layer through said spaced openings.

12. The light-emitting device of claim 11, wherein said spaced opening having a dimension greater than said third opening.

13. The light-emitting device of claim 11, wherein two adjacent said third openings have a first spacing d1 and two adjacent said spacing openings have a second spacing d2, and d1 and d2 are related as: d2≈2d1.

14. The light-emitting device of claim 11, wherein two adjacent said third openings have a first spacing d1 and two adjacent said spacing openings have a second spacing d2, and d1 and d2 are related as: d2≈3d1.

15. The light-emitting device of claim 8, wherein said second electrode being distributed in a central area of said semiconductor structure, while the second pad portion is located at a center and said second extension extends in opposite directions from said second pad portion.

16. The light-emitting device of claim 1, wherein a ratio of a diameter of said fourth opening to a diameter of said second pad portion is a range of 1:2 to 1:20.

17. The light-emitting device of claim 7, wherein said third opening has the shape of a strip.

18. The light-emitting device of claim 1, wherein said protective layer has a thickness greater than or equal to 200 nm.

19. A light-emitting system including a plurality of light-emitting diodes, each light-emitting diode comprising:
a semiconductor structure including a first semiconductor layer, a light-emitting layer and a second semiconductor layer from up down, and said semiconductor structure having a mesa which exposes said second semiconductor layer;
a transparent conductive layer formed on the first semiconductor layer, and having a first opening to expose a portion of a surface of the first semiconductor layer;
a protective layer formed over said transparent conductive layer; and
a first electrode formed over least a portion of said protective layer, and having a pad portion and an extension connected to said pad portion;
wherein said protective layer having a second opening at a position corresponding to said pad portion to expose a portion of a surface of said first semiconductor layer and a portion of a surface of said transparent conductive layer, and said pad portion of said first electrode is in contact with both said first semiconductor layer and said transparent conductive layer through said second opening.

20. The light-emitting system of 19, wherein said second opening has a larger size than said first opening, and said pad portion of said first electrode is in contact with said first semiconductor layer and said transparent conductive layer.
